(19) United States
(12) Patent Application Publication
(10) Pub. No.: US 2026/0033155 A1
(43) Pub. Date: Jan. 29, 2026

(54) DISPLAY DEVICE AND MANUFACTURING METHOD OF THE SAME

(71) Applicant: Japan Display Inc., Tokyo (JP)

(72) Inventors: Tomokazu ISHIKAWA, Tokyo (JP); Takamitsu FUJIMOTO, Tokyo (JP); Sho YANAGISAWA, Tokyo (JP); Hiraaki KOKAME, Tokyo (JP); Ryota TAKASAKI, Tokyo (JP)

(73) Assignee: Japan Display Inc., Tokyo (JP)

(21) Appl. No.: 19/277,619

(22) Filed: Jul. 23, 2025

(30) Foreign Application Priority Data
Jul. 24, 2024 (JP) 2024-118336

(51) Int. Cl. H10K 59/122; H10K 59/12; H10K 59/80; H10K 59/88

(52) U.S. Cl. CPC H10K 59/122; H10K 59/1201; H10K 59/8722; H10K 59/88

(57) ABSTRACT

According to one embodiment, a display device includes a substrate having a display area, pixels in the display area, a dummy pixel area including dummy pixels and surrounding the display area, a first partition surrounding each of the pixels and the dummy pixels, a second partition in a first area surrounding the dummy pixel area and a second area surrounding the first area and having apertures. Each of the first and second partitions has a lower portion and an upper portion having an end portion protruding relative to a side surface of the lower portion. Further, a first aperture pattern of the second partition in the first area and a second aperture pattern of the second partition in the second area differ from each other.

### CROSS-REFERENCE TO RELATED APPLICATION

This application is based upon and claims the benefit of priority from Japanese Patent Application No. 2024-118336, filed Jul. 24, 2024, the entire contents of which are incorporated herein by reference.

### FIELD

Embodiments described herein relate generally to a display device and a manufacturing method of the same.

### BACKGROUND

Recently, display devices to which an organic light emitting diode (OLED) is applied as a display element have been put into practical use. In this type of display devices, a technique for improving the yield is required.

### BRIEF DESCRIPTION OF THE DRAWINGS

FIG. 1 is a view showing a configuration example of a display device according to an embodiment.

FIG. 2 is a schematic plan view showing an example of the layout of subpixels.

FIG. 3 is a schematic cross-sectional view of the display device along the III-III line of FIG. 2.

FIG. 4 is a schematic plan view of a display device according to an embodiment.

FIG. 5 is a schematic cross-sectional view of a surrounding area of a display device according to an embodiment.

FIG. 6 is a schematic plan view in which the area surrounded by the frame VI of FIG. 4 is enlarged.

FIG. 7 is a schematic plan view showing an example of the aperture pattern of a partition in the display area.

FIG. 8 is a schematic plan view showing an example of the aperture pattern of the partition in a dummy pixel area.

FIG. 9A is a schematic plan view showing an example of the aperture pattern of the partition in a first area.

FIG. 9B is a schematic plan view showing another example of the aperture pattern of the partition in the first area.

FIG. 10A is a schematic plan view showing an example of the aperture pattern of the partition in a second area.

FIG. 10B is a schematic plan view showing still another example of the aperture pattern of the partition in the second area.

FIG. 10C is a schematic plan view showing still another example of the aperture pattern of the partition in the second area.

FIG. 11 is a schematic view for explanations on an example of a measurement method of the aperture ratio.

FIG. 12 is a schematic plan view of a mother substrate according to an embodiment.

FIG. 13 is a schematic plan view of a panel unit according to an embodiment.

FIG. 14 is a flowchart showing an example of the manufacturing method of the display device according to an embodiment.

FIG. 15A is a schematic cross-sectional view showing the manufacturing process of the display device.

FIG. 15B is a schematic cross-sectional view showing a process following FIG. 15A.

FIG. 15C is a schematic cross-sectional view showing a process following FIG. 15B.

FIG. 15D is a schematic cross-sectional view showing a process following FIG. 15C.

FIG. 15E is a schematic cross-sectional view showing a process following FIG. 15D.

FIG. 15F is a schematic cross-sectional view showing a process following FIG. 15E.

FIG. 15G is a schematic cross-sectional view showing a process following FIG. 15F.

FIG. 16A is a schematic view for explanations on a process of forming a resin layer.

FIG. 16B is a schematic view for explanations on a process following FIG. 16A.

FIG. 17 is a schematic plan view showing an example of a coating area of an outer resin layer.

FIG. 18 is a schematic plan view of a partition of a comparative example.

FIG. 19A is a schematic cross-sectional view showing a state where droplets are discharged in forming a resin layer.

FIG. 19B is a schematic cross-sectional view showing a state where droplets shown in FIG. 19A have adhered to a sealing layer.

FIG. 19C is a schematic cross-sectional view showing a state where droplets shown in FIG. 19B are spreading.

### DETAILED DESCRIPTION

In general, according to one embodiment, a display device includes a substrate having a display area for displaying an image, a plurality of pixels provided in the display area, the pixels each including a lower electrode, an upper electrode located above the lower electrode, and an organic layer located between the lower electrode and the upper electrode and emitting light based on application of voltage, a dummy pixel area surrounding the display area and including a plurality of dummy pixels not displaying images, a first partition surrounding each of the plurality of pixels and the plurality of dummy pixels, a second partition, which is provided in a first area surrounding the dummy pixel area and a second area surrounding the first area and has a plurality of apertures. Each of the first partition and the second partition has a lower portion having conductivity and an upper portion having an end portion protruding relative to a side surface of the lower portion. Further, a first aperture pattern of the second partition in the first area and a second aperture pattern of the second partition in the second area differ from each other.

Further, according to one embodiment, a display device manufacturing method includes forming a first partition surrounding each of a plurality of pixels in a display area and a plurality of dummy pixels in a dummy pixel area surrounding the display area, forming a second partition having a plurality of apertures in a first area surrounding the dummy pixel area and a second area surrounding the first area, forming a frame-shaped outer resin layer surrounding the display area such that the outer resin layer overlaps at least the second area, and forming an inner resin layer covering an area inside the outer resin layer. Further, a first aperture pattern of the second partition in the first area and a second aperture pattern of the second partition in the second area differ from each other.

These configurations of the display device and manufacturing method of the same can improve the yield of the display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X- direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

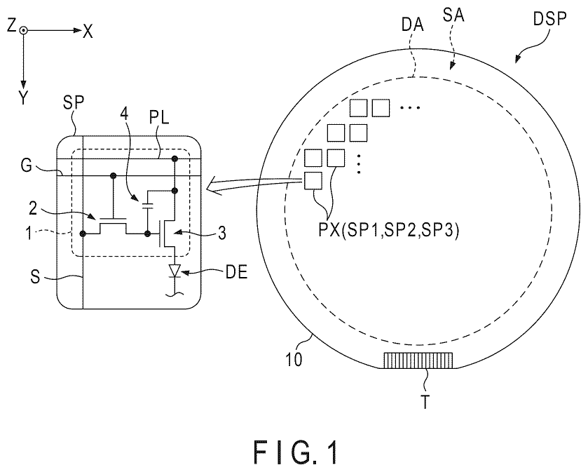

FIG. 1 is a view showing a configuration example of a display device DSP according to the present embodiment. The display device DSP comprises an insulating substrate 10. The substrate 10 has a display area DA for displaying an image and a surrounding area SA around the display area DA. The substrate 10 may be glass or a resinous film having flexibility.

In the present embodiment, the substrate 10 and the display area DA have a circular shape in plan view. The shape of each of the substrate 10 and the display area DA in plan view is not limited to a circular shape and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP which display different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit, which applies voltage and signals for driving the display device DSP is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines G supplying the pixel circuit 1 of each subpixel SP with scanning signals, a plurality of signal lines S supplying the pixel circuit 1 of each subpixel SP with video signals, and a plurality of power lines PL. In the example of FIG. 1, the scanning lines G and the power lines PL extend in the X-direction, and the signal lines S extend in the Y-direction. However, the configuration is not limited to this example.

The gate electrode of the pixel switch 2 is connected to the scanning line G. One of the source electrode and the drain electrode of the pixel switch 2 is connected to the signal line S. The other is connected to the gate electrode of the drive transistor 3 and the capacitor 4. In the drive transistor 3, one of the source electrode and the drain electrode is connected to the power line PL and the capacitor 4. The other is connected to a display element DE.

The configuration of the pixel circuit 1 is not limited to the example of the figure. For example, the pixel circuit 1 may comprise more thin-film transistors and capacitors.

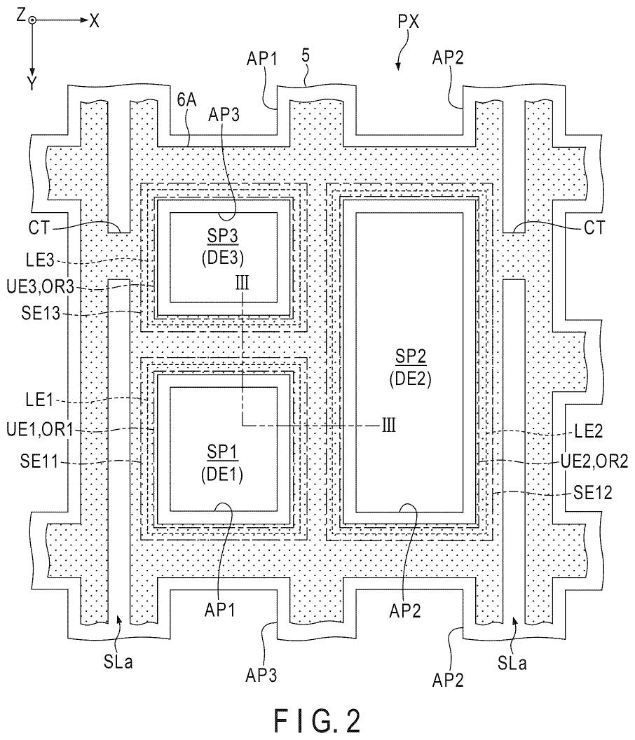

FIG. 2 is a schematic plan view showing an example of the layout of the subpixels SP1, SP2, and SP3 constituting one pixel PX. In the example of FIG. 2, the subpixels SP1 and SP3 are arranged in the Y-direction. Each of the subpixels SP1 and SP3 is adjacent to the subpixel SP2 in the X-direction.

When the subpixels SP1, SP2, and SP3 are arranged in this layout, in the display area DA, a column in which the subpixels SP1 and SP3 are alternately arranged in the Y-direction and a column in which the plurality of subpixels SP2 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2 and AP3 in the subpixels SP1, SP2 and SP3, respectively. In the example of FIG. 2, each of the pixel apertures AP1, AP2, and AP3 has a rectangular shape. The planar size of the pixel aperture AP1 is greater than that of the pixel aperture AP3. The planar size of the pixel aperture AP2 is greater than that of the pixel aperture AP1. The shapes of the pixel apertures AP1, AP2, and AP3 are not limited to this example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

The lower electrode LE1, the upper electrode UE1, and the organic layer OR1 constitute a display element DE1 of the subpixel SP1. The lower electrode LE2, the upper electrode UE2, and the organic layer OR2 constitute a display element DE2 of the subpixel SP2. The lower electrode LE3, the upper electrode UE3, and the organic layer OR3 constitute a display element DE3 of the subpixel SP3. Each of the display elements DE1, DE2, and DE3 may further have a cap layer to be described later. The rib layer 5 surrounds each of the display elements DE1, DE2, and DE3.

A conductive partition 6A (the first partition) is provided above the rib layer 5. The partition 6A functions as lines that supply the upper electrodes UE1, UE2, and UE3 with common voltage. The partition 6A entirely overlaps the rib layer 5 and has the same planar shape as that of the rib layer 5. The partition 6A surrounds the subpixels SP1, SP2, and SP3.

The partition 6A has a plurality of slits SLa extending in the Y-direction. In the example of FIG. 2, the subpixels SP1, SP2, and SP3 constituting one pixel PX are provided between two slits SLa in the X-direction. Further, the partition 6A has a connection unit CT, which connects portions divided by the slits SLa to each other. The layout of the slits SLa and the connection unit CT is not limited to the example of FIG. 2. For example, slits SLa that are continuous between the both end portions in the Y-direction of the display area DA may be provided.

Sealing layers SE11, SE12 and SE13 are provided in the subpixels SP1, SP2 and SP3, respectively. The sealing layer SE11 continuously covers the display element DE1 and the partition 6A around the display element DE1. The sealing layer SE12 continuously covers the display element DE2 and the partition 6A around the display element DE2. The sealing layer SE13 continuously covers the display element DE3 and the partition 6A around the display element DE3.

In the example of FIG. 2, the sealing layers SE11, SE12, and SE13 do not overlap the slits SLa. As another example, at least one of the sealing layers SE11, SE12, and SE13 may overlap the slit SLa.

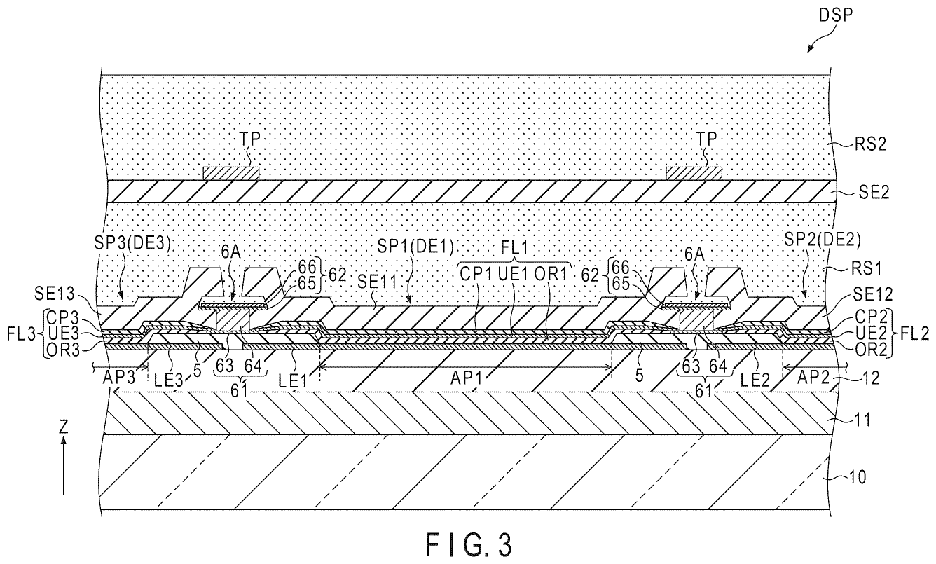

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, the scanning lines G, the signal lines S, and the power line PL shown in FIG. 1. The circuit layer 11 is covered with an organic insulating layer 12. The organic insulating layer 12 functions as a planarization film, which planarizes irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. The periphery portions of the lower electrodes LE1, LE2, and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6A has a conductive lower portion 61 provided on the rib layer 5 and an upper portion 62 provided on the lower portion 61. The upper portion 62 has a width greater than that of the lower portion 61. That is, the partition 6A has an overhang shape in which the both end portions of the upper portion 62 protrude relative to the side surfaces of the lower portion 61.

In the example of FIG. 3, the lower portion 61 has a bottom layer 63 provided on the rib layer 5, and a stem layer 64 provided on the bottom layer 63. For example, the bottom layer 63 is formed to be thinner than the stem layer 64. In the example of FIG. 3, the both end portions of the bottom layer 63 protrude relative to the side surfaces of the stem layer 64.

In the example of FIG. 3, the upper portion 62 has a first top layer 65 and a second top layer 66 provided on the first top layer 65. For example, the width of the second top layer 66 is slightly less than that of the first top layer 65. The configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portions 61 of the partition 6A.

The display element DE1 has a cap layer CP1 covering the upper electrode UE1. The display element DE2 has a cap layer CP2 covering the upper electrode UE2. The display element DE3 has a cap layer CP3 covering the upper electrode UE3. The cap layers CP1, CP2, and CP3 function as optical adjustment layers, which improve the extraction efficiency of the light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12 and SE13 are provided in the subpixels SP1, SP2 and SP3, respectively. Further, the sealing layer SE11 continuously covers the stacked film FL1 and the partition 6A around the stacked film FL1. Further, the sealing layer SE12 continuously covers the stacked film FL2 and the partition 6A around the stacked film FL2. Further, the sealing layer SE13 continuously covers the stacked film FL3 and the partition 6A around the stacked film FL3.

In the example of FIG. 3, the sealing layer SE11 located on the partition 6A between the subpixels SP1 and SP2 is spaced apart from the sealing layer SE12 located on this partition 6A. The sealing layer SE11 located on the partition 6A between the subpixels SP1 and SP3 is spaced apart from the sealing layer SE13 located on this partition 6A. Two of the sealing layers SE11, SE12, and SE13 may contact each other above the partition 6A.

For example, a gap is formed between each of the sealing layers SE11, SE12, and SE13 and the upper portion 62 of the partition 6A. The stacked films FL1, FL2 and FL3 may be provided in at least part of these gaps.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

In the example of FIG. 3, a touch panel electrode TP for detecting touch operations by a user is provided on the sealing layer SE2. For example, the touch panel electrode TP is formed of a metal material and has the same shape as that of the partition 6A in plan view.

A cover member such as a polarizer, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). For example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating material) such as an epoxy resin or an acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), and an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is composed of a plurality of thin films including a light emitting layer. As an example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z-direction. The organic layers OR1, OR2, and, OR3 each may have other structures such as a tandem structure including a plurality of light emitting layers.

Each of the cap layers CP1, CP2, and CP3 has,

for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

Each of the bottom layer 63 and stem layer 64 of the partition 6A is formed of a metal material. For the metal material of the bottom layer 63, for example, molybdenum, titanium, a titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material.

The first top layer 65 of the partition 6A is formed of, for example, a metal material. The second top layer 66 of the partition 6A is formed of, for example, a conductive oxide. For the metal material forming the first top layer 65, for example, titanium, a titanium nitride, molybdenum, tungsten, a molybdenum-tungsten alloy, or a molybdenum-niobium alloy can be used. For the conductive oxide forming the second top layer 66, for example, ITO or IZO can be used. The upper portion 62 may have three or more layers or may consist of a single layer. The upper portion 62 may further have a layer formed of an insulating material.

Common voltage is applied to the partition 6A. This common voltage is applied to each of the upper electrodes UE1, UE2, and UE3 in contact with the lower portions 61. The lower electrodes LE1, LE2, and LE3 are supplied with pixel voltages according to the video signals of the signal lines S through the respective pixel circuits 1 provided in the subpixels SP1, SP2, and SP3.

The organic layers OR1, OR2, and OR3 emit light in response to the application of a voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light in the same color (for example, white). In this case, the display device DSP may comprise a color filter that converts the light emitted from the light emitting layers into light in the colors corresponding to those of the subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

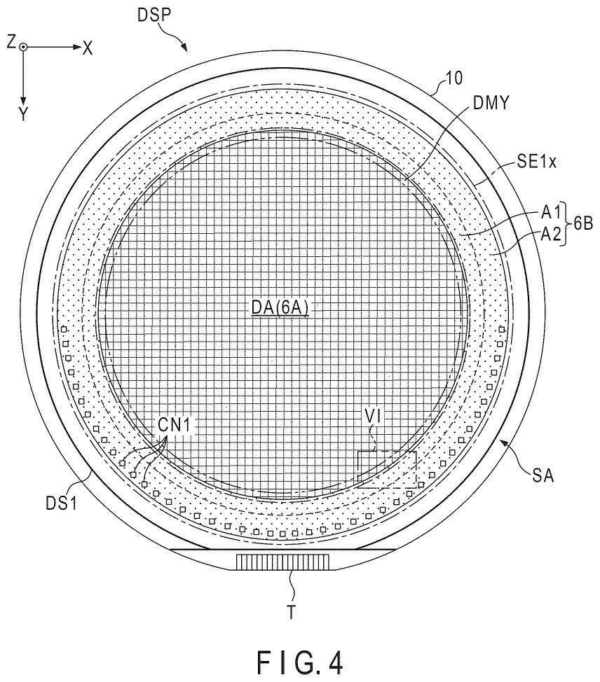

FIG. 4 is a schematic plan view of the display device DSP. In the example of this figure, a dummy pixel area DMY, a partition 6B (the second partition), a sealing layer SE1x, and a dam structure DS1 are provided in the surrounding area SA. For example, each of the dummy pixel area DMY, the partition 6B, the sealing layer SE1x, and the dam structure DS1 has a circular shape concentric with the display area DA.

The dummy pixel area DMY surrounds the display area DA. The partition 6B is located on the outside of the dummy pixel area DMY (a side farther from the display area DA) and surrounds the display area DA and the dummy pixel area DMY.

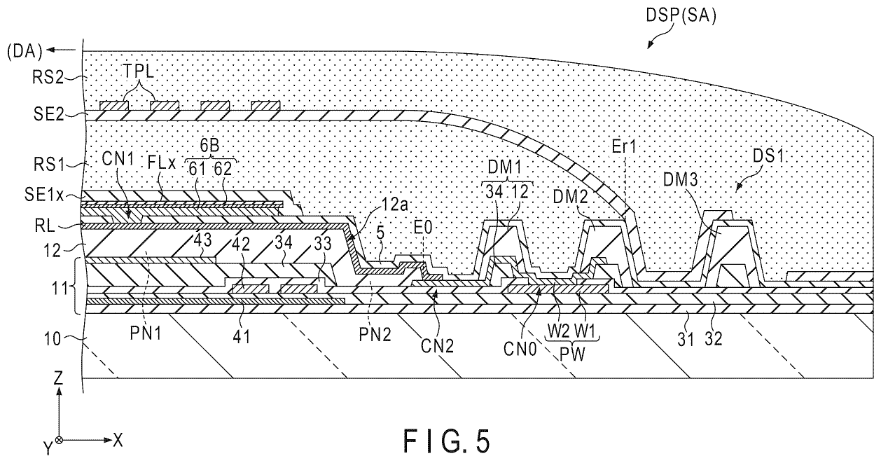

In the present embodiment, the partition 6B has a first area A1 surrounding the dummy pixel area DMY and a second area A2 surrounding the first area A1. The second area A2 is connected to the relay layer RL and the power supply line PW that are provided on the lower layer via a plurality of contact portions CN1 (refer to FIG. 5). The power supply line PW is connected to the terminal portion T and supplies the partition 6B with common voltage. The partition 6A provided in the display area DA is connected to the partition 6B. That is, common voltage of the power supply line PW is supplied to the partition 6A via the partition 6B and then supplied to the upper electrodes UE1, UE2, and UE3, which contact the partition 6A. In the example of FIG. 4, the plurality of contact portions CN1 are arcuately provided in the terminal portion T side.

The sealing layer SE1x covers the entire partition 6B, that is, the first area A1 and the second area A2. In the example of FIG. 4, the sealing layer SE1x surrounds the display area DA. The sealing layer SE1x is formed of the same inorganic insulating material as those of the sealing layers SE11, SE12, and SE13.

The dam structure DS1 is located on the outside of the partition 6B and surrounds the display area DA, the dummy pixel area DMY, the partition 6B, and the sealing layer SE1x. The terminal portion T is located on the outside of the dam structure DS1.

FIG. 5 is a schematic cross-sectional view of the surrounding area SA of the display device DSP. The partition 6B has the same structure as that of the partition 6A. That is, the partition 6B has the lower portion 61 and the upper portion 62. The lower portion 61 has the bottom layer 63 and the stem layer 64. The upper portion 62 has the first top layer 65 and the second top layer 66. At the end portion of the partition 6B, the upper portion 62 protrudes relative to the side surfaces of the lower portion 61.

The circuit layer 11 shown in FIG. 3 has inorganic insulating layers 31, 32, and 33 formed of an inorganic insulating material, an organic insulating layer 34 formed of an organic insulating material, and metal layers 41, 42, and 43. The inorganic insulating layer 31 covers the upper surface of the substrate 10. The metal layer 41 is provided on the inorganic insulating layer 31. The inorganic insulating layer 32 covers the metal layer 41. The metal layer 42 is provided on the inorganic insulating layer 32. The inorganic insulating layer 33 covers the metal layer 42. The organic insulating layer 34 covers the inorganic insulating layer 33. The metal layer 43 is provided on the organic insulating layer 34 and is covered with the organic insulating layer 12. For example, the dam structure DS1 comprises

a dam portion DM1, a dam portion DM2 surrounding the dam portion DM1, and a dam portion DM3 surrounding the dam portion DM2. For example, each of the dam portions DM1, DM2, and DM3 has a circular shape surrounding the display area DA. The number of the dam portions that the dam structure DS1 comprises is not limited to three.

Each of the dam portions DM1, DM2, and DM3 protrudes toward the upper side of the substrate 10. In the example of FIG. 5, the dam portion DM1 consists of the organic insulating layers 12 and 34. Similarly, the dam portions DM2 and DM3 consist of the organic insulating layers 12 and 34. In other words, in the present embodiment, the dam portions DM1, DM2, and DM3 are formed of the same materials as the organic insulating layers 12 and 34 in the same layers as the organic insulating layers 12 and 34.

The power line PW to which common voltage is applied is provided below the dam portions DM1 and DM2. The power line PW has a first line W1 formed of the metal layer 42 and a second line W2 formed of the metal layer 43.

In the example of FIG. 5, the first line W1 and the second line W2 contact each other in a contact portion CNO located between the dam portions DM1 and DM2. Part of the second line W2 is located between the organic insulating layers 12 and 34 in each of the dam portions DM1 and DM2.

In the surrounding area SA, the conductive relay layer RL, which connects the partition 6B and the power supply line PW to each other, and the rib layer 5 are provided. For example, the relay layer RL is formed of the same material and process as those of the lower electrodes LE1, LE2, and LE3 described above.

The relay layer RL is located on the display area DA side (the left side in the figure) relative to the dam portion DM1 and covers the organic insulating layer 12. The rib layer 5 continuously covers the relay layer RL and the dam portions DM1, DM2, and DM3.

The partition 6B is provided on the rib layer 5. The partition 6B contacts the relay layer RL in the contact portion CN1 shown also in FIG. 4. More specifically, the rib layer 5 is open in the contact portions CN1. The lower portion 61 of the partition 6B (specifically, the bottom layer 63) contacts the relay layer RL through this aperture. The contact portion CN1 is provided above the organic insulating layer 12.

The relay layer RL contacts the second line W2 of the power supply line PW in a contact portion CN2. The contact portion CN2 is located between the end portion E0 of the organic insulating layer 12 and the dam portion DM1 in plan view.

A stacked film FLx is provided on the partition 6B. The partition 6B and the stacked film FLx are covered with the sealing layer SE1x. The stacked film FLx is formed by the same process and material as those of any of the stacked films FL1, FL2, and FL3 shown in FIG. 3. The sealing layer SE1x is formed by the same process and material as those of any of the sealing layers SE11, SE12, and SE13 shown in FIG. 3. The present embodiment assumes cases where the stacked film FLx and the sealing layer SE1x are respectively formed as the same process and material as those of the stacked film FL3 and the sealing layer SE13, respectively. That is, the stacked film FLx has the upper electrode UE3, the organic layer OR3, and the cap layer CP3.

The resin layer RS1, the sealing layer SE2, and the resin layer RS2 shown in FIG. 3 are provided above the sealing layer SE1x. Further, a touch panel line TPL connected to the touch panel electrode TP shown in FIG. 3 is provided on the sealing layer SE2. For example, the touch panel line TPL is formed of the same material as that of the touch panel electrode TP.

The resin layer RS1 covers the sealing layer SE1x and the rib layer 5. In the manufacturing of the display device DSP, the dam portions DM1, DM2, and DM3 function to dam up the resin layer RS1 that is uncured. In the example of FIG. 5, an end portion Er1 of the resin layer RS1 is located above the dam portion DM2. That is, the resin layer RS1 partly covers the dam portions DM1 and DM2. The position of the end portion Er1 is not limited to this example.

The sealing layer SE2 covers the end portion Er1 of the resin layer RS1. The sealing layer SE2 contacts the rib layer 5 in an area located further outward than the end portion Er1 (the right side in the figure). In the example of FIG. 5, the sealing layer SE2 is removed in the vicinity of the dam portion DM3. The resin layer RS1 is surrounded by the sealing layer SE1x, the rib layer 5, and the sealing layer SE2. This configuration prevents the moisture intrusion into the resin layer RS1.

As shown in FIG. 5, the organic insulating layer 12 may have a first portion PN1 and a second portion PN2 thinner than the first portion PN1. The second portion PN2 is formed in the periphery of the first portion PN1. That is, the second portion PN2 covers the first portion PN1 in plan view. Each of the partition 6B, the stacked film FLx, and the sealing layer SE1x is located above the first portion PN1.

In the example of FIG. 5, the organic insulating layer 34 is provided below the first portion PN1 but not provided below the second portion PN2. A step portion 12a is formed on the organic insulating layer 12 in the vicinity of the end portion of the organic insulating layer 34. For example, of the organic insulating layer 12, the portion that is closer to the dam portion DM1 relative to the step portion 12a corresponds to the second portion PN2.

The relay layer RL covers the first portion PN1, the second portion PN2, and the step portion 12a. If the organic insulating layer 12 does not have the second portion PN2, the step portion 12a becomes steeper. If the relay layer RL is formed to cover this steep step portion 12a, the relay layer RL may be deformed. To the contrary, providing the second portion PN2 can decrease the influence of the step portion 12a, and thus the relay layer RL can be sufficiently formed.

The sectional structure shown in FIG. 5 can be applied to any position of the surrounding area SA except the vicinity of the terminal portion T. The configuration of the surrounding area SA is not necessarily limited to that shown in FIG. 5. For example, the organic insulating layer 12 may not have the second portion PN2. The shape of the structure for connecting the partition 6B and the power supply line PW together can be changed according to the position of the power supply line PW, the layer configuration of the circuit layer 11, and the like.

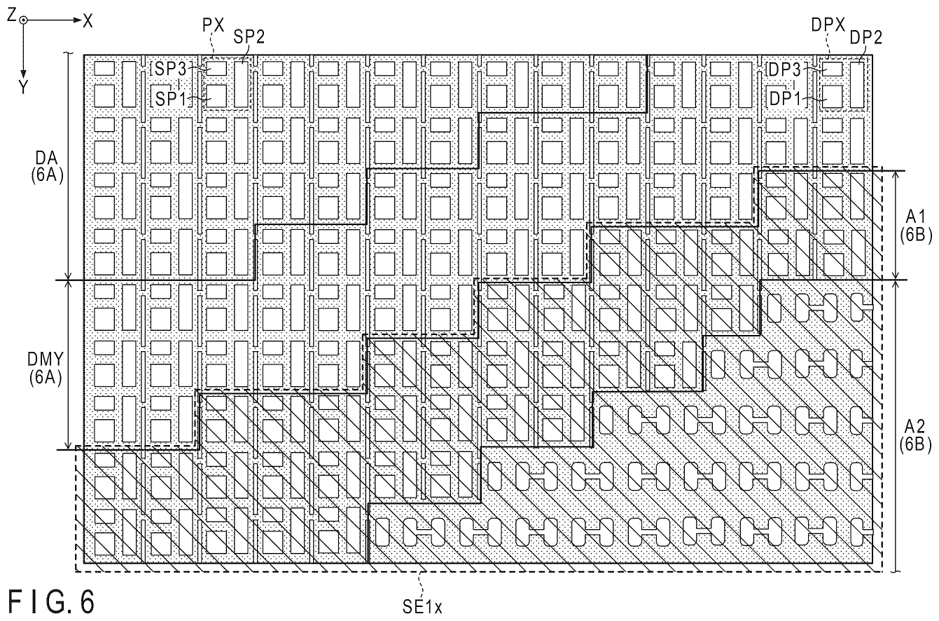

FIG. 6 is a schematic plan view in which the area surrounded by the frame VI of FIG. 4 is enlarged.

A plurality of dummy pixels DPX are provided in the dummy pixel area DMY. For example, each dummy pixel DPX includes dummy subpixels DP1, DP2, and DP3. Each of the dummy subpixels DP1, DP2, and DP3 has the configuration similar to that of the respective subpixels SP1, SP2, and SP3 shown in FIG. 2.

That is, the dummy subpixel DP1 comprises the lower electrode LE1, the organic layer OR1, the upper electrode UE1, and the sealing layer SE11. The dummy subpixel DP2 comprises the lower electrode LE2, the organic layer OR2, the upper electrode UE2, and the sealing layer SE12. The dummy subpixel DP3 comprises the lower electrode LE3, the organic layer OR3, the upper electrode UE3, and the sealing layer SE13.

However, the dummy subpixels DP1, DP2, and DP3 are configured not to emit light. This configuration may be realized by, for example, disconnecting part of the pixel circuit 1 in each of the dummy subpixels DP1, DP2, and DP3. The pixel apertures AP1, AP2, and AP3 may be omitted in the dummy subpixels DP1, DP2, and DP3, respectively. Thus, the rib layer 5 is interposed between the organic layers OR1, OR2, and OR3 and the lower electrodes LE1, LE2, and LE3. Thus, a voltage for making the organic layers OR1, OR2, and OR3 to emit light is not supplied to these organic layers OR.

Part of the partition 6A is located in the dummy pixel area DMY and surrounds each of the plurality of dummy pixels DPX. More specifically, the partition 6A surrounds each of the dummy subpixels DP1, DP2, and DP3.

The partitions 6A and 6B are continuously formed. For example, of these continuously formed partitions, the partition 6B corresponds to the portion that overlaps the sealing layer SE1x. In FIG. 5, the sealing layer SE1x is indicated by broken-line pattern.

The lower electrodes LE1, LE2, and LE3 and a pixel circuit PC are provided in the display area DA and the dummy pixel area DMY but not provided in the first area A1 and the second area A2. Thus, in other words, the partition 6B is the portion in which the lower electrodes LE1, LE2, and LE3 and the pixel circuit PC are not provided, of the portions formed continuously in the display area DA and the surrounding area SA.

In the present embodiment, the outer shape of each of the display area DA, the dummy pixel area DMY, the first area A1, and the second area A2 is a circular shape. As shown in FIG. 6, this outer shape can be achieved by forming each of the boundary between the display area DA and the dummy pixel area DMY, the boundary between the dummy pixel area DMY and the first area A1, and the boundary between the first area A1 and the second area A2 in a stair-step shape.

In each of the first area A1 and the second area A2, the partition 6B has a plurality of apertures. In the present embodiment, an aperture pattern in the first area A1 (the first aperture pattern) and an aperture pattern in the second area A2 (the second aperture pattern) differ from each other. Further, the aperture pattern in the second area A2 and an aperture pattern of the partition 6A (the third aperture pattern) in the display area DA and the dummy pixel area DMY differ from each other.

The aperture patterns of the first area A1 and the second area A2 may affect the quality of the shape of the resin layer RS1. This point is to be described in detail later. In terms of forming the resin layer RS1 with an appropriate shape, the second area A2 preferably has a shape that suppresses spreading of the resin material of the uncured resin layer RS1 more than the first area A1. This relationship can be achieved, for example, by making the aperture ratio of the partition 6B in the second area A2 lower than that of the partition 6B in the first area A1.

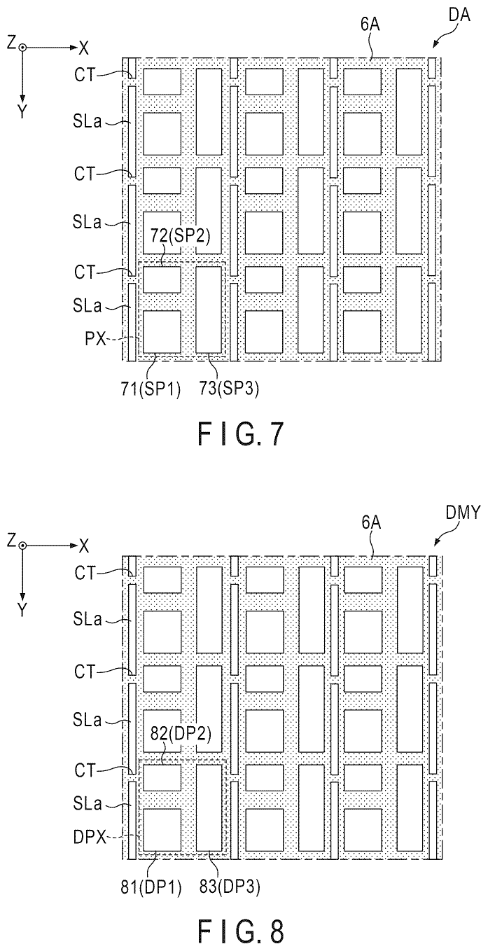

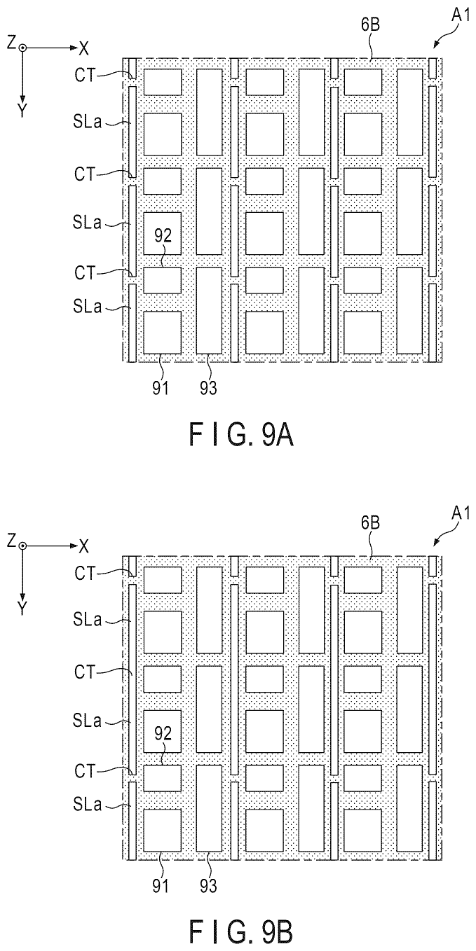

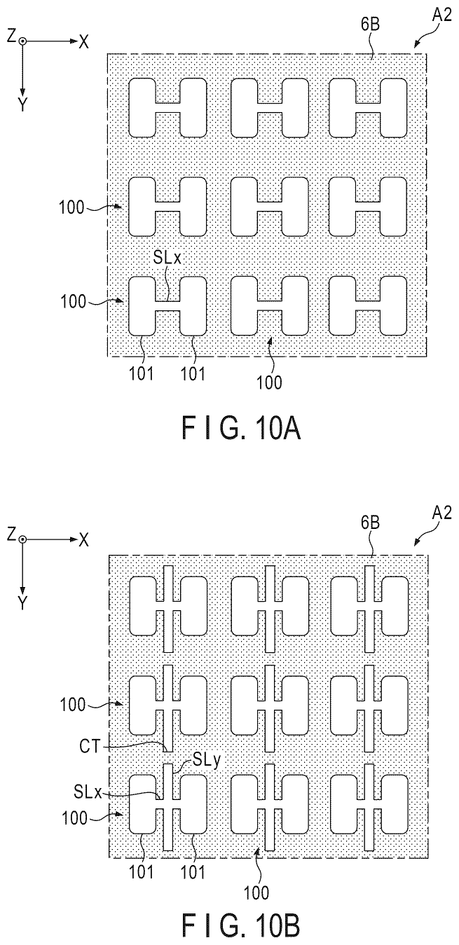

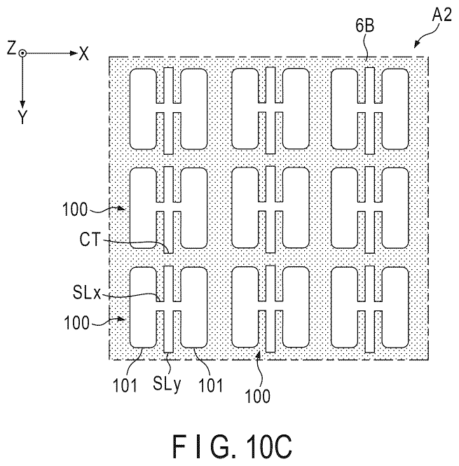

The following describes examples of the configurations applicable to the aperture patterns of the partitions 6A and 6B in the display area DA, the dummy pixel area DMY, the first area A1, and the second area A2 with reference to FIG. 7, FIG. 8, FIG. 9A, FIG. 9B, FIG. 10A, FIG. 10B, and FIG. 10C. The aperture patterns of the partitions 6A and 6B refer to the patterns formed by the apertures and slits shown in these figures.

FIG. 7 is a schematic plan view showing an example of the aperture pattern of the partition 6A in the display area DA. The partition 6A shown in this figure has the same shape as the one shown in FIG. 2 and has the apertures 71, 72, and 73 in each of the pixels PX. The apertures 71, 72, and 73 have rectangular shapes surrounding the subpixels SP1, SP2, and SP3, respectively. Further, the partition 6A has a plurality of slits SLa each located between adjacent pixels PX. A connection unit CT is formed between the slits SLa arranged in the Y-direction.

FIG. 8 is a schematic plan view showing an example of the aperture pattern of the partition 6A in the dummy pixel area DMY. The partition 6A has apertures 81, 82, 83 in each of the dummy pixels DPX. The apertures 81, 82, and 83 have rectangular shapes surrounding the respective dummy subpixels DP1, DP2, and DP3. Further, the partition 6A has the plurality of slits SLa each located between adjacent dummy pixels DPX. The connection unit CT is formed between the slits SLa arranged in the Y-direction.

The apertures 81, 82, and 83 shown in FIG. 8 have the same shapes as those of the respective apertures 71, 72, and 73 shown in FIG. 7. The shape of the slits SLa shown in FIG. 8 and their positions relative to the apertures 81, 82, and 83 are the same as the shape of the slits SLa shown in FIG. 7 and their positions relative to the apertures 71, 72, and 73. That is, in the examples shown in FIG. 7 and FIG. 8, the partitions 6A in the display area DA and the dummy pixel area DMY have the same aperture pattern.

As another example, the apertures 81, 82, and 83 may be different from the shapes of the apertures 71, 72, and 73. The shape of the slits SLa may differ between the display area DA and the dummy pixel area DMY. In that case, the aperture pattern of the partition 6A differs between the display area DA and the dummy pixel area DMY.

FIG. 9A is a schematic plan view showing an example of the aperture pattern of the partition 6B in the first area A1. In the example shown in this figure, the partition 6B has a plurality of apertures 91, 92, and 93 (the first apertures) and the plurality of slits SLa (the first slits) provided between the apertures 91, 92, and 93 adjacent to one another in the X-direction. The connection unit CT is formed between the slits SLa arranged in the Y-direction.

The apertures 91, 92, and 93 shown in FIG. 9A have the same shapes as those of the respective apertures 71, 72, and 73 shown in FIG. 7. The shape of the slits SLa shown in FIG. 9A and their positions relative to the apertures 91, 92, and 93 are the same as the shape of the slits SLa shown in FIG. 7 and their positions relative to the apertures 71, 72, and 73. That is, in the examples of FIG. 7 and FIG. 9A, the partition 6A in the display area DA and the partition 6B in the first area A1 have the same aperture pattern. Further, in cases where the dummy pixel area DMY adopts the configuration shown in FIG. 8, the partition 6A in the dummy pixel area DMY and the partition 6B in the first areas A1 have the same aperture pattern.

FIG. 9B is a schematic plan view showing another example of the aperture pattern of the partition 6B in the first area A1. In the same manner as the one shown in FIG. 9A, the partition 6B has the plurality of apertures 91, 92, and 93 and the slits SLa. However, the slit SLa shown in FIG. 9B is formed longer than the slit SLa shown in FIG. 9A.

For example, the slit SLa shown in FIG. 9A and the slit SLa in the display area DA and the dummy pixel area DMY have the same length. Specifically, these lengths are approximately equivalent to the width in the Y-direction of the aperture 93. On the other hand, the slit SLa shown in FIG. 9B has the length approximately twice the width in the Y-direction of the aperture 93.

The shapes of the slits SLa in the respective display area DA, the dummy pixel area DMY, and the first area A1 are not limited to those shown in FIG. 7, FIG. 8, FIG. 9A, and FIG. 9B. As another example, the slit SLa in the first area A1 may be shorter than the slits SLa in the display area DA and the dummy pixel area DMY. A continuous slits SLa may be provided across the display area DA, the dummy pixel area DMY, and the first area A1.

FIG. 10A is a schematic plan view showing an example of the aperture pattern of the partition 6B in the second area A2. In the example of this figure, the partition 6B has a plurality of apertures 101 (the second apertures) and a plurality of slits SLx extending in the X-direction (the second slits). The plurality of apertures 101 are arranged in the X-direction and the Y-direction with certain intervals. For example, the aperture 101 has a rectangular shape elongated in the Y-direction but may have a different shape. The slit SLx connects two apertures 101 arranged in the X-direction to each other.

From another view point, in the example of FIG. 10A, one slit SLx and two apertures 101 connected by this slit SLx forms one unit pattern 100. Further, a plurality of unit patterns 100 are arranged in the X-direction and the Y-direction with intervals. For example, the arrangement pitch of the unit patterns 100 in the X-direction are equivalent to the arrangement pitch of the pixels PX in the X-direction. Further, the arrangement pitch of the unit patterns 100 in the Y-direction are equivalent to the arrangement pitch of the pixels PX in the Y-direction.

FIG. 10B is a schematic plan view showing another example of the aperture pattern of the partition 6B in the second area A2. In the manner same as the one in FIG. 10A, the partition 6B has the plurality of apertures 101 and the plurality of slits SLx extending in the X-direction. Further, the partition 6B further has a plurality of slits SLy (the third slits) extending in the Y-direction and intersecting the slits SLx.

In the example of FIG. 10B, the unit pattern 100 is constituted by two apertures 101, one slit SLx, and one slit SLy. The slit SLy of the unit patterns 100 adjacent in the Y-direction are spaced apart from each other. That is, the connection unit CT is formed between these slits SLy.

FIG. 10C is a schematic plan view showing still another example of the aperture pattern of the partition 6B in the second area A2. In the same manner as the one shown in FIG. 10B, the partition 6B has the plurality of apertures 101 and the plurality of slits SLx and SLy. However, the aperture 101 in the example of FIG. 10C is longer in the Y-direction than the one shown in FIG. 10B.

For example, the length in the Y-direction of the aperture 101 shown in FIG. 10B is smaller than the length in the Y-direction of the aperture 73 shown in FIG. 7. On the other hand, the length in the Y-direction of the aperture 101 shown in FIG. 10C is equivalent to the length of the aperture 73.

The above aperture patterns shown in FIG. 7, FIG. 8, FIG. 9A, FIG. 9B, FIG. 10A, FIG. 10B, and FIG. 10C are mere examples. In addition to these, various aperture patterns are adopted in the display area DA, the dummy pixel area DMY, the first area A1, and the second area A2.

As described above, the aperture ratio of the partition 6B in the second area A2 is lower than the aperture ratio of the partition 6B in the first area A1. The following describes an example of the measurement method of these aperture ratios.

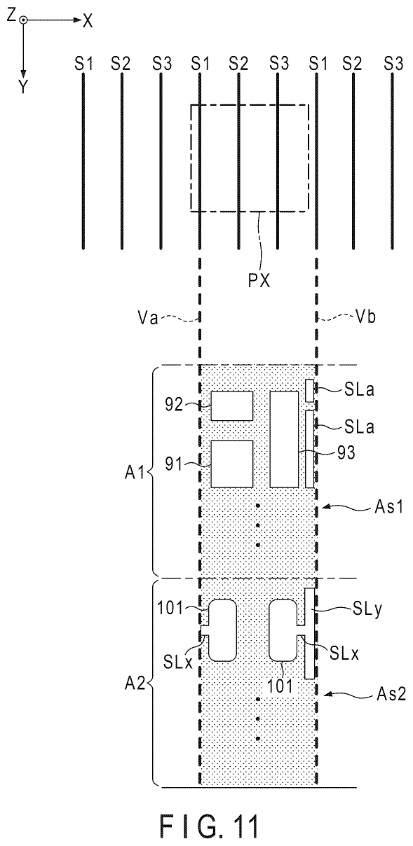

FIG. 11 is a schematic view for explanations on an example of the measurement method of the aperture ratios. The plurality of signal lines S (refer to FIG. 1) are provided in the display area DA. These signal lines S include signal lines S1, S2, S3 providing the pixel circuits 1 of the respective subpixels SP1, SP2, and SP3 with video signals. The signal lines S1, S2, and S3 are arranged in the X-direction in this order.

Each of the interval between two adjacent signal lines S1, the interval between two adjacent signal lines S2, and the interval between two adjacent signal lines S3 corresponds to the width in the X-direction of the pixel PX. For example, the signal lines S1, S2, and S3 are bent to the first area A1 and the second area A2 and is connected to the terminal portion T.

As shown in FIG. 11, virtual lines Va and Vb are defined. These virtual lines are virtual extensions of two adjacent signal lines S1. Further, of the first area A1, the portion interposed between these virtual lines Va and Vb is called a sub-area As1. Further, of the second area A2, the portion interposed between these virtual lines Va and Vb is called a sub-area As2.

The aperture ratio of the partition 6B in the first areas A1 corresponds to the proportion of the planar size of the aperture portion included in the sub-area As1 relative to the planar size of the sub-area As1. For example, when the first area A1 has the configurations shown in FIG. 9A or FIG. 9B, the apertures 91, 92, and 93 included in the sub-area As1 and the slit SLa correspond to the aperture.

The aperture ratio of the partition 6B in the second area A2 corresponds to the proportion of the planar size of the aperture portion included in the sub-area As2 relative to the planar size of the sub-area As2. For example, when the second area A2 has the configuration shown in FIG. 10B, the aperture 101, the slit SLx, and the slit SLy included in the sub-area As2 correspond to the apertures.

For example, the aperture ratio of the partition 6B in the first area A1 is 50% or more. Further, the aperture ratio of the partition 6B in the second area A2 is 25% or more and less than 50%. When the display area DA, the dummy pixel area DMY, and the first area A1 have the configurations shown in FIG. 7, FIG. 8, and FIG. 9A, respectively, these areas have the same aperture ratio.

FIG. 11 shows as examples cases where the aperture ratios of the partitions 6B in the first area A1 and the second area A2 are defined using the virtual lines Va and Vb of the signal line S1. Alternatively, these aperture ratios may be defined by a virtual line corresponding to the extension of the signal line S2 or a virtual line corresponding to the extension of the signal line S3. For example, when the calculations based on the virtual lines Va and Vb of the signal line S1, the calculation based on the signal line S2, and the calculation based on the signal line S3 provide different aperture ratios of the first area A1, the average value of these aperture ratios may be used as the aperture ratio of the first area A1. The same method can be applied to the aperture ratio of the second area A2.

The following describes an example of the manufacturing method of the display device DSP. In the manufacturing of the display device DSP, a large mother substrate is fabricated, the mother substrate comprising a plurality of areas (panel units) each including a unit corresponding to the display device DSP.

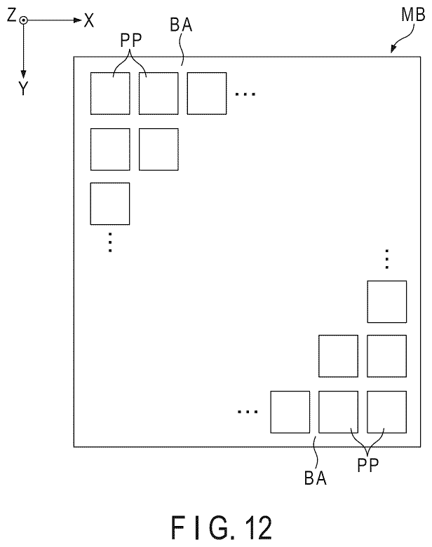

FIG. 12 is a schematic plan view of a mother substrate MB (a mother substrate for a display device) according to the present embodiment. For example, the mother substrate MB has a rectangular shape as shown in the figure. However, the mother substrate MB may have another shape such as a circular shape.

The mother substrate MB comprises a plurality of panel units PP provided in a matrix and a margin area BA around these panel units PP. In the example of FIG. 12, the panel units PP are arranged in the X-direction and the Y-direction via the margin area BA. The layout of the panel units PP in the mother substrate MB is not limited to this example. As another example, some of the panel units PP may be arranged without interposing the margin area BA therebetween.

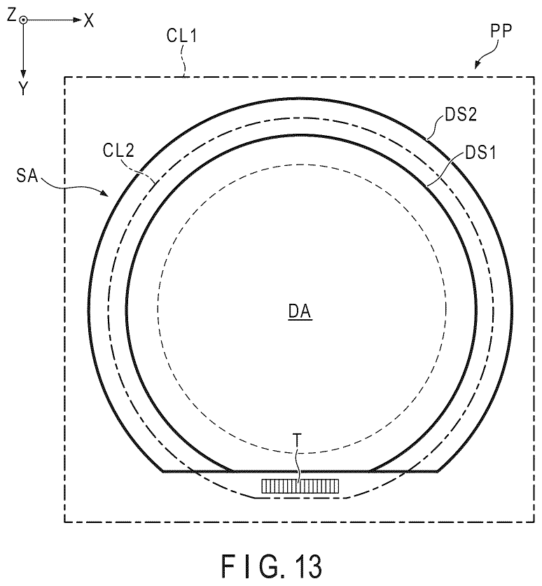

FIG. 13 is a schematic plan view of the panel unit PP. The outer shape of the panel unit PP corresponds to a cut line CL1 for cutting out each panel unit PP from the mother substrate MB.

Each panel unit PP has the display area DA and the surrounding area SA. The surrounding area SA in the panel unit PP corresponds to the area between the display area DA and the cut line CL1.

The surrounding area SA further has a cut line CL2, which is the outer shape of the substrate 10 of the display device DSP. In the manufacturing of the display device DSP, the panel unit PP is cut out from the mother substrate MB along the cut line CL1. Further, the display device DSP is cut out from the panel unit PP along the cut line CL2.

In addition to the dam structure DS1, the panel unit PP comprises a dam structure DS2. The dam structure DS2 functions to dam up the resin layer RS2 that is uncured. For example, the dam structure DS2 has a plurality of dam portions formed of the organic insulating layers 12 and 34 in the same manner as the dam portions DM1, DM2, and DM3.

The dam structure DS1 is located between the cut line CL2 and the display area DA and surrounds the display area DA. The dam structure DS2 is located between the cut lines CL1 and CL2 and surrounds the cut line CL2. In the example of FIG. 13, the dam structures DS1 and DS2 merge in the vicinity of the terminal portion T. This merged portion passes between the terminal portion T and the display area DA.

The most part of the cut line CL2 is located between the dam structures DS1 and DS2. In the example of FIG. 13, the cut line CL2 is located on the outside of the dam structures DS1 and DS2 in the vicinity of the terminal portion T. That is, the cut line CL2 traverses the dam structure DS2 in the vicinity of the terminal portion T.

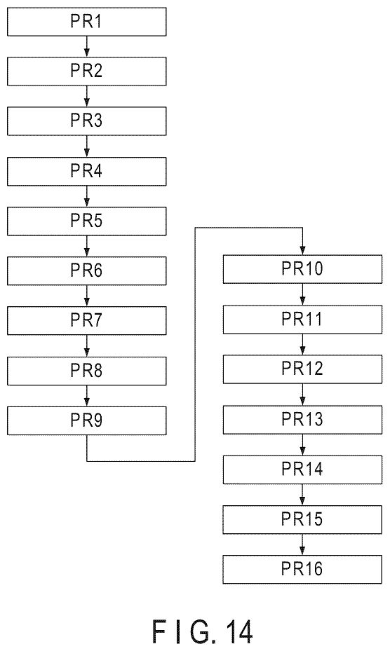

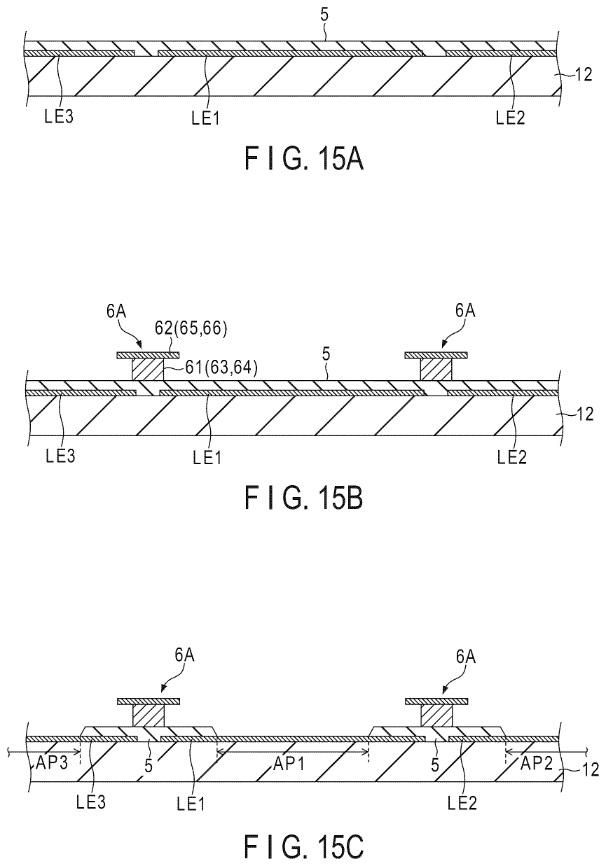

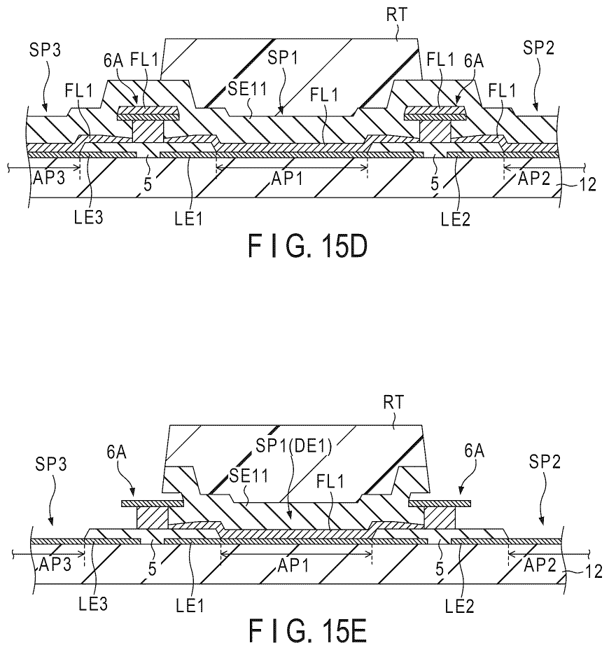

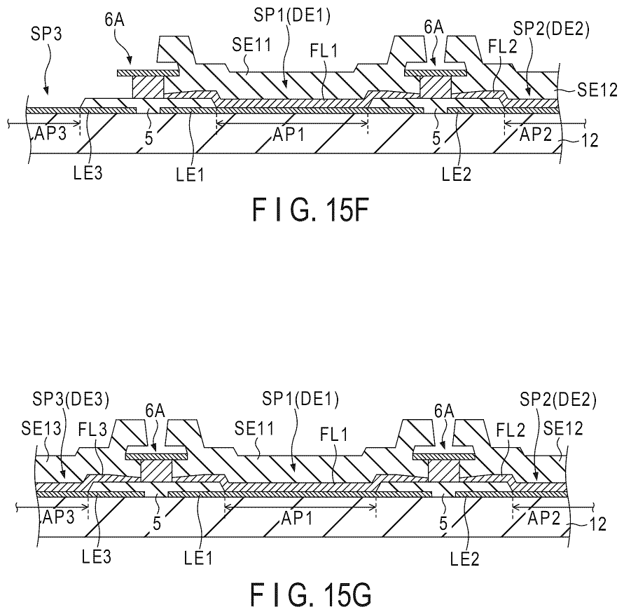

FIG. 14 is a flowchart showing an example of the manufacturing method of the display device DSP. FIG. 15A to FIG. 15G are schematic cross-sectional views showing the manufacturing process of the display device DSP. FIG. 15A to FIG. 15G mainly focus on the display area DA and omit the elements below the organic insulating layer 12.

In forming the panel units PP, first, the circuit layer 11 including the inorganic insulating layers 31, 32, and 33, the organic insulating layer 34, the metal layers 41, 42, and 43, and the like are formed on the substrate 10 of the mother substrate MB (process PR1 in FIG. 14). Further, the organic insulating layer 12 covering the circuit layer 11 is formed (process PR2 in FIG. 14). At this time, the dam structures DS1 and DS2 are formed as well.

After the process PR2, as shown in FIG. 15A, the lower electrodes LE1, LE2, and LE3 are formed on the organic insulating layer 12 (process PR3 in FIG. 14). Further, as shown in FIG. 15A, the rib layer 5 covering the lower electrodes LE1, LE2, and LE3 is formed in the entire mother substrate MB (process PR4 in FIG. 14). At this time, the pixel apertures AP1, AP2, and AP3 are not provided in the rib layer 5. The rib layer 5 may be formed by chemical vapor deposition (CVD).

After the formation of the rib layer 5, the partition 6A is formed on the rib layer 5, as shown in FIG. 15B (process PR5 in FIG. 14). The partition 6B of the surrounding area SA is formed together with the partition 6A. For example, in forming the partitions 6A and 6B, material layers of the bottom layer 63, the stem layer 64, the first top layer 65, and the second top layer 66 are formed over the entire mother substrate MB. Further, a resist having the shape corresponding to the partitions 6A and 6B is provided on these layers. The partitions 6A and 6B can be formed by etching each layer using this resist as a mask.

Next, as shown in FIG. 15C, the pixel apertures AP1, AP2, and AP3 are formed in the rib layer 5 (process PR6 in FIG. 14). The pixel apertures AP1, AP2, and AP3 may be formed prior to the formation of the partitions 6A and 6B.

After the process PR6, a process for forming the display element DE1 is performed (process PR7 in FIG. 14). in forming the display element DE1, the stacked film FL1 and the sealing layer SE11 are formed first as shown in FIG. 15D. As shown in FIG. 3, the stacked film FL1 includes, the organic layer OR1, which is in contact with the lower electrode LE1 through the pixel aperture AP1, the upper electrode UE1, which covers the organic layer OR1, and the cap layer CP1, which covers the upper electrode UE1. For example, the organic layer OR1, the upper electrode UE1, and the cap layer CP1 may be formed by vapor deposition. For example, the sealing layer SE11 may be formed by CVD.

The stacked film FL1 and the sealing layer SE11 are formed in the entire mother substrate MB including the surrounding area SA and the margin area BA as well as the display area DA of each panel unit PP. The stacked film FL1 is divided by the partitions 6A and 6B having overhang shapes. The sealing layer SE11 continuously covers the portions into which the stacked film FL1 is divided, and the partitions 6A and 6B.

Subsequently, the stacked film FL1 and the sealing layer SE11 are patterned. In this patterning, as shown in FIG. 15D, a resist RT is provided on the sealing layer SE11. The resist RT covers the subpixel SP1 and part of the partition 6A around the subpixel SP1.

Subsequently, an etching process using the resist RT as a mask is performed. By this process, of the stacked film FL1 and the sealing layer SE11, the portions that are exposed from the resist RT are removed, as shown in FIG. 15E. In other words, of the stacked film FL1 and the sealing layer SE11, the portions that overlap the lower electrode LE1 remain, and the other portions are removed. This process forms the display element DE1 in the subpixel SP1. For example, this etching process removes the stacked film FL1 and the sealing layer SE11 in the surrounding area SA and the margin area BA. This etching process may include wet etching and dry etching performed in order for the sealing layer SE11, the cap layer CP1, the upper electrode UE1, and the organic layer OR1. After these etching processes, the resist RT is removed (stripped).

After the process PR7, a process for forming the display element DE2 is performed (process PR8 in FIG. 14). The display element DE2 can be formed by the same procedure as that of the display element DE1. That is, in forming the display element DE2, the stacked film FL2 and the sealing layer SE12 are formed in the entire mother substrate MB. The stacked film FL2 includes the organic layer OR2, which is in contact with the lower electrode LE2 through the pixel aperture AP2, the upper electrode UE2, which covers the organic layer OR2, and the cap layer CP2, which covers the upper electrode UE2, as shown in FIG. 3.

The organic layer OR2, the upper electrode UE2, and the cap layer CP2 may be formed by, for example, vapor deposition. The sealing layer SE12 may be formed by, for example, CVD. Patterning these stacked film FL2 and sealing layer SE2 forms the display element DE2 in the subpixel SP2, as shown in FIG. 15F. For example, the etching in this patterning removes the stacked film FL2 and the sealing layer SE12 in the surrounding area SA and the margin area BA.

After the process PR8, a process for forming the display element DE3 is performed (process PR9 in FIG. 14). The display element DE3 can be formed by the same procedures as those of the display elements DE1 and DE2. Specifically, when the display element DE3 is formed, the stacked film FL3 and the sealing layer SE13 are formed in the entire mother substrate MB. The stacked film FL3 includes, the organic layer OR3, which is in contact with the lower electrode LE3 through the pixel aperture AP3, the upper electrode UE3, which covers the organic layer OR3, and the cap layer CP3, which covers the upper electrode UE3, as shown in FIG. 3.

The organic layer OR3, the upper electrode UE3, and the cap layer CP3 may be formed by, for example, vapor deposition. The sealing layer SE13 may be formed by, for example, CVD. Patterning these stacked film FL3 and sealing layer SE13 forms the display element DE3 in the subpixel SP3, as shown in FIG. 15G.

For example, the etching in this patterning removes the stacked film FL3 and the sealing layer SE13 in the most of the surrounding area SA and margin area BA. Of the stacked film FL3 and the sealing layer SE13, the portion that covers the partition 6B remains. In this manner, the remaining portion corresponds to the stacked film FLx and the sealing layer SE1x.

Here, the above description assumes that the display elements DE1, DE2, and DE3 are formed in this order. However, the display elements DE1, DE2, and DE3 may be formed in another order.

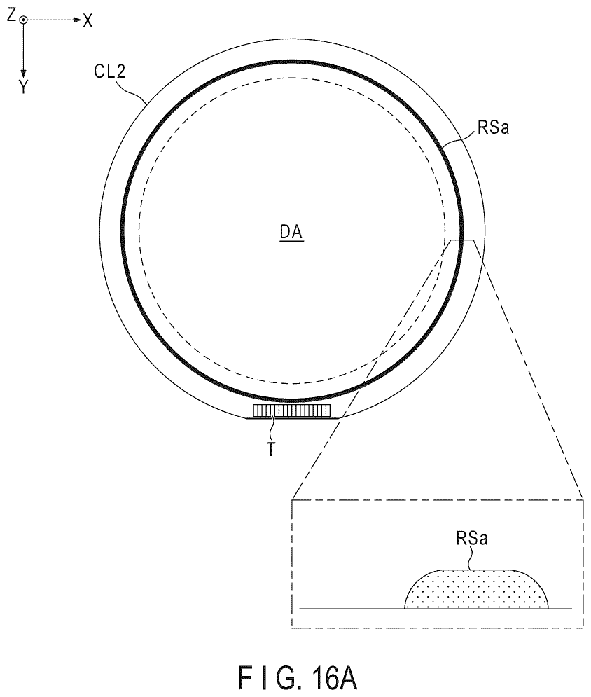

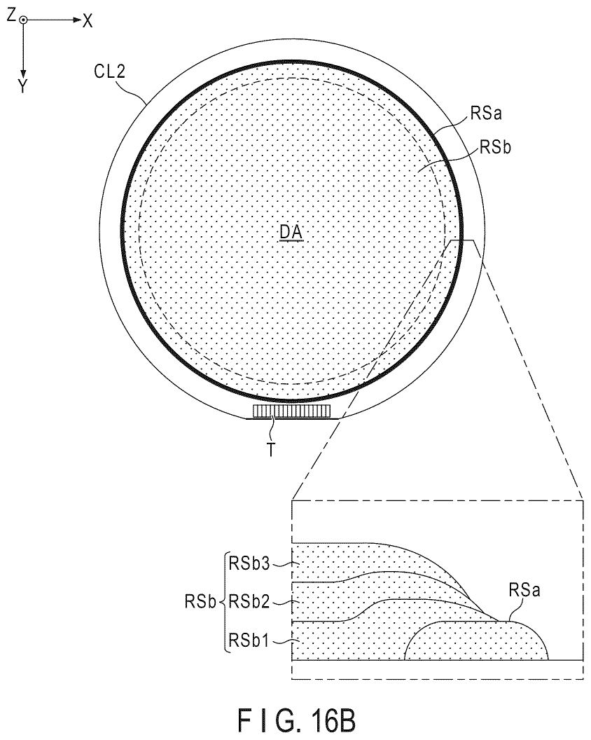

After the process PR9, the resin layer RS1 is formed, for example, by the ink-jet method (process PR10 in FIG. 14). FIG. 16A and FIG. 16B are schematic views for explanations on the process PR10 of forming the resin layer RS1. In the process PR10, first, an outer resin layer RSa having a frame shape is formed as shown in FIG. 16A. The outer resin layer RSa has a circular shape surrounding the display area DA and is located in the vicinity of the outer circumference of the area in which the resin layer RS1 is to be formed. The lower part of FIG. 16A shows the cross section of the outer resin layer RSa.

The outer resin layer RSa is formed by applying the resin material of the resin layer RS1 in a ring shape using an inkjet device and temporarily curing the resin material by ultraviolet light irradiation. For example, in this temporary curing, the resin material is thickened to the degree that it does not completely cure.

Next, as shown in FIG. 16B, an inner resin layer RSb completely covering the area inside the outer resin layer RSa is formed. The inner resin layer RSb is formed by applying resin material to fill the area inside the outer resin layer RSa using an ink-jet device.

Such application may be performed in multiple steps. The cross-sectional view shown in the lower side of FIG. 16B shows a state where the inner resin layer RSb is coated in three separate times, respectively for inner resin layers RSb1, RSb2, and RSb3. For example, the inner resin layers RSb1, RSb2, and RSb3 have the same thicknesses.

Immediately after coating, the inner resin layer RSb spreads outwardly. The outer resin layer RSa suppresses the spreading of the inner resin layer RSb. After the formation of the outer resin layer RSa, the outer resin layer RSa and the inner resin layer RSb are permanently cured. These permanently cured outer resin layer RSa and inner resin layer RSb correspond to the resin layer RS1.

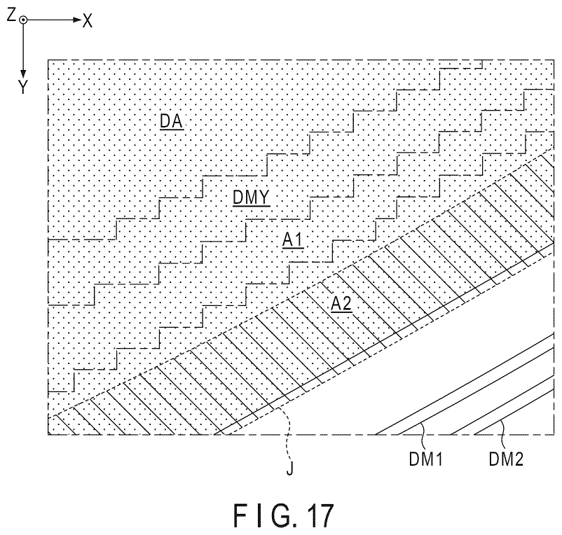

FIG. 17 is a schematic plan view showing an example of the area where droplets of resin materials are discharged in forming the outer resin layer RSa (hereinafter referred to as a coating area J). The coating area J overlaps the second area A2 but does not overlap the first area A1. In the example of FIG. 17, part of the second area A2 does not overlap the coating area J in the vicinity of the boundary between the first area A1 and the second area A2. For example, the coating area J slightly overlaps the area between the second area A2 and the dam portion DM1.

The coating area J corresponds to the area to which the resin material immediately after being discharged from the ink-jet device adheres. The resin material after adhesion spreads over time and may reach the dam portions DM1 and DM2.

After forming the resin layer RS1 in the process PR10, the sealing layer SE2 is formed, for example by CVD (process PR11 in FIG. 14). Furthermore, etching is performed to remove the rib layer 5 and the sealing layer SE2 that cover the terminal portion T (process PR12 in FIG. 14). The etching is, for example, dry etching.

After the process PR12, the touch panel electrode TP and the touch panel line TPL are formed on the sealing layer SE2 (process PR13 in FIG. 14). Further, the resin layer RS2 is formed (process PR14 in FIG. 14). The resin layer RS2 may be formed inside the dam structure DS2 by, for example, the ink-jet method. The dam structure DS2 functions to dam up the resin layer RS2 that is uncured.

After the process PR14, the mother substrate MB is cut along the cut line CL1 (process PR15 in FIG. 14). Further, the panel unit PP is cut along the cut line CL2 (process PR16 in FIG. 14). This completes the display device DSP. For example, laser cutting with infrared irradiation along the cut lines CL1 and CL2 may be adopted for cutting in the processes PR15 and PR16. The cutting in the processes PR15 and PR16 may be performed by other methods such as scribe cutting.

The embodiment described above can improve the yield of the display device DSP. The stacked films FL1, FL2, and FL3 formed by vapor deposition may have poor adherence to the base. Thus, the stacked films FL1, FL2, and FL3 and the sealing layers SE11, SE12, and SE13 covering these stacked films may be stripped from the base in the manufacturing of the display device DSP.

This stripping tends to occur in cases where the stacked films FL1, FL2, and FL3 are continuously formed in a wide range. In the display area DA, the stacked films FL1, FL2, and FL3 are divided into pieces by the partition 6A. Thus, the stripping is suppressed.

In the present embodiment, the partition 6B having the plurality of apertures is provided in the surrounding area SA. This configuration divides the stacked films FL1, FL2, and FL3 into pieces and suppresses the stripping in the surrounding area SA as well.

Further, the configuration of the display device DSP according to the present embodiment can achieve, for example, effects described below.

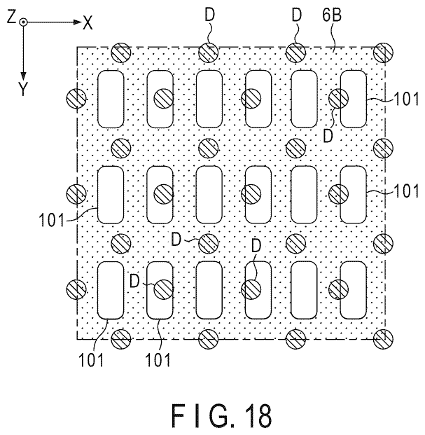

FIG. 18 is a schematic cross-sectional view showing the partition 6B according to a comparative example for the present embodiment. In the same manner as the aperture patterns shown in FIG. 10A and FIG. 10B, the partition 6B in this figure has the plurality of apertures 101. However, the partition 6B does not have the slits SLx and SLy. Thus, the apertures 101 are independent from one another.

The circles with diagonal-line pattern represent droplets D of the resin material that are discharged toward the mother substrate MB in forming the outer resin layer RSa and the inner resin layer RSb of the resin layer RS1. The droplets D are discharged from a plurality of nozzles of the ink-jet device. These nozzles are arranged with certain intervals. Thus, the droplets D adhere to the mother substrate MB with certain spatial intervals.

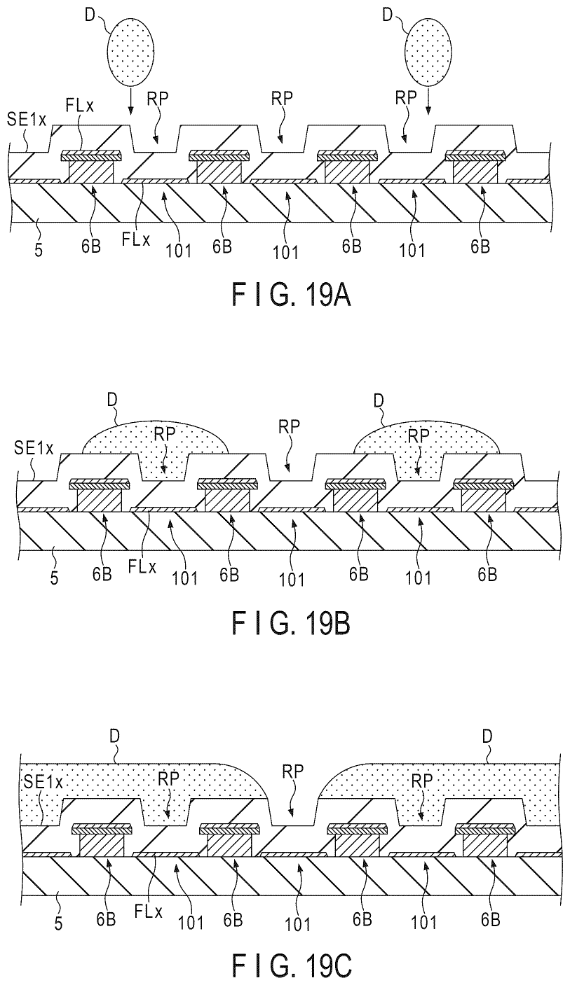

FIG. 19A, FIG. 19B, and FIG. 19C are schematic cross-sectional views showing the droplets D shown in FIG. 18 adhering to the mother substrate MB and then spreading. The partitions 6B are covered with the stacked film FLx and the sealing layer SE1x. A recess portion RP caused by the aperture 101 is formed on the upper surface of the sealing layer SE1x.

As shown in FIG. 19A, the droplets D are discharged toward the sealing layer SE1x. In FIG. 19B, the droplets D adhere to the sealing layer SE1x. Subsequently, the droplets D spread as shown in FIG. 19C.

When droplets D adhere to a position overlapping the recess portion RP, the interior of the recess portion RP is filled with the droplets D. In addition, the droplets D spread to the recess portion RP that does not overlap the droplets D immediately after the adhesion. However, as in the recesses RP shown in the center of FIG. 19C, a recess portion RP (uncoated portion) into which the droplets D do not flow due to the surface tension of the step portion of the sealing layer SE1x may be formed. Such uncoated portion may cause shape deformation or break in the touch panel line TPL formed above the resin layer RS1. Irregularities in the appearance of the display device DSP may occur due to the uncoated portion.

In contrast, as shown in FIG. 10A, FIG. 10B, and FIG. 10C, when two apertures 101 are connected by the slit SLx and the droplets D flow into either of the apertures 101, the droplets D are to flow through the recess (groove) of the sealing layer SE1x formed by the slit SLx and into the other aperture 101. This suppresses the occurrence of uncoated portion as shown in FIG. 19C and forms the resin layer RS1 with an appropriate shape.

The higher the aperture ratio of the partition 6B, the more easily droplets D adhere to the recess portion RP of the sealing layer SE1x resulting from each aperture, thereby increasing the effect of suppressing the uncoated portion. However, the higher aperture ratio of the partition 6B tends to make the droplets D more readily to spread.

The droplets D that are too prone to spreading may cause other problems. That is, a portion where the outer resin layer RSb shown in FIG. 16A spreads locally toward the display area DA may be formed, resulting in the occurrence of irregularities corresponding to the shape of the outer resin layer RSa on the upper surface of the resin layer RS1 even if the inner resin layer RSb is applied on this portion. Such irregularities may cause deformation and disconnection of the touch panel line TPL as described above, and may also cause unevenness in the appearance of the display device DSP.

In the present embodiment, the aperture pattern of the partition 6B differs between the first area A1 and the second area A2 outside it. Further, the coating area J of the outer resin layer RSa overlaps the second area A2 but does not overlap the first area A1. The second area A2 has the aperture ratio lower than that of the first area A1. Thus, the droplets D do not readily spread in the second area A2. In forming the outer resin layer RSa, the spreading of the droplets D toward the first area A1, the dummy pixel area DMY and the display area DA inside it are suppressed. This can suppress the irregularities on the upper surface of the resin layer RS1.

Suppressing the irregularities on the upper surface of the resin layer RS1 can suppress the application failure of liquid resins such as various resists applied after the formation of the resin layer RS1 as well. Such liquid resins include, for example, a resist for processing the rib layer 5 and the sealing layer SE2 in the process PR12, and a resist for processing the touch panel electrode TP and the touch panel line TPL in the process PR13.

The display device DSP may include a plurality of color filters corresponding to the colors of the subpixels SP1, SP2, and SP3, and a black matrix located at the boundaries of the subpixels SP1, SP2, and SP3. For example, these color filters and black matrix may be provided above the sealing layer SE2. Suppressing the irregularities on the upper surface of the resin layer RS1 can suppress application failure of the resins that are materials forming the color filters and black matrix.

In each of the above embodiments, the term “partition” includes various overhanging structures.

Even if the overhanging structure has a shape different from the partition disclosed in each embodiment, the portion protruding laterally corresponds to the “upper portion” and the portion recessed below of the portion corresponds to the “lower portion”.

All of the display devices that can be implemented by a person of ordinary skill in the art through arbitrary design changes to the display device disclosed as each embodiment described above come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a substrate having a display area for displaying images;
a plurality of pixels provided in the display area, the pixels each including a lower electrode, an upper electrode located above the lower electrode, and an organic layer located between the lower electrode and the upper electrode and emitting light based on application of voltage;
a dummy pixel area surrounding the display area and including a plurality of dummy pixels which do not display images;
a first partition surrounding each of the plurality of pixels and the plurality of dummy pixels; and
a second partition, which is provided in a first area surrounding the dummy pixel area and a second area surrounding the first area and has a plurality of apertures, wherein
each of the first partition and the second partition has a lower portion having conductivity and an upper portion having an end portion protruding relative to a side surface of the lower portion, and
a first aperture pattern of the second partition in the first area is different from a second aperture pattern of the second partition in the second area.

2. The display device of claim 1, wherein
the first aperture pattern is equivalent to a third aperture pattern of the first partition in the display area, and
the second aperture pattern differs from the third aperture pattern.

3. The display device of claim 1, wherein
an aperture ratio of the second partition in the first area is higher than an aperture ratio of the second partition in the second area.

4. The display device of claim 3, wherein
the aperture ratio of the second partition in the first area is 50% or more.

5. The display device of claim 3, wherein
the aperture ratio of the second partition in the second area is 25% or more and less than 50%.

6. The display device of claim 1, wherein
the first aperture pattern has:
a plurality of first apertures; and
a plurality of first slits, each of which is provided between the first apertures adjacent to each other in a first direction and extends in a second direction intersecting the first direction.

7. The display device of claim 6, wherein
the second aperture pattern has:
a plurality of second apertures; and
a plurality of second slits, each of which connects the second apertures adjacent to each other in the first direction and extends in the first direction.

8. The display device of claim 7, wherein
the second aperture pattern further has a plurality of third slits intersecting the first slits.

9. The display device of claim 1, further comprising:
a sealing layer formed of an inorganic insulating material covering the second partition in the first area and the second area; and
a resin layer covering the sealing layer.

10. The display device of claim 1, wherein
each of the display area, the dummy pixel area, the first area, and the second area has a circular shape.

11. A display device manufacturing method, the method comprising:
forming a first partition surrounding each of a plurality of pixels in a display area and a plurality of dummy pixels in a dummy pixel area surrounding the display area;
forming a second partition having a plurality of apertures in a first area surrounding the dummy pixel area and a second area surrounding the first area;
forming a frame-shaped outer resin layer surrounding the display area such that the outer resin layer overlaps at least the second area; and
forming an inner resin layer covering an area inside the outer resin layer, wherein
a first aperture pattern of the second partition in the first area is different from a second aperture pattern of the second partition in the second area.

12. The display device manufacturing method of claim 11, wherein
the outer resin layer and the inner resin layer are formed by an ink-jet method, and
a coating area to which droplets for forming the outer resin layer are discharged overlaps the second area but does not overlap the first area.

13. The display device manufacturing method of claim 11, wherein
the first aperture pattern is equivalent to a third aperture pattern of the first partition in the display area, and
the second aperture pattern differs from the third aperture pattern.

14. The display device manufacturing method of claim 11, wherein
an aperture ratio of the second partition in the first area is higher than an aperture ratio of the second partition in the second area.

15. The display device manufacturing method of claim 14, wherein
the aperture ratio of the second partition in the first area is 50% or more.

16. The display device manufacturing method of claim 14, wherein
the aperture ratio of the second partition in the second area is 25% or more and less than 50%.

17. The display device manufacturing method of claim 11, wherein
the first aperture pattern has:
a plurality of first apertures; and
a plurality of first slits, each of which is provided between the first apertures adjacent to each other in a first direction and extends in a second direction intersecting the first direction.

18. The display device manufacturing method of claim 17, wherein
the second aperture pattern has:
a plurality of second apertures; and
a plurality of second slits, each of which connects the second apertures adjacent to each other in the first direction and extends in the first direction.

19. The display device manufacturing method of claim 18, wherein
the second aperture pattern further has a plurality of third slits intersecting the first slits.

20. The display device manufacturing method of claim 11, wherein
each of the display area, the dummy pixel area, the first area, and the second area has a circular shape.
